(19) United States
(12) Patent Application Publication
(10) Pub. No.: US 2024/0053245 A1
(43) Pub. Date: Feb. 15, 2024

(54) DETERMINING RELATIVE PERMEABILITY IN A ROCK SAMPLE

(71) Applicant: Halliburton Energy Services, Inc., Houston, TX (US)

(72) Inventors: Xiaobo NIE, Houston, TX (US); Jonas TOELKE, Houston, TX (US); Qian FANG, Sugar Land, TX (US)

(73) Assignee: Halliburton Energy Services, Inc., Houston, TX (US)

(21) Appl. No.: 18/124,961

(22) Filed: Mar. 22, 2023

Related U.S. Application Data
(60) Provisional application No. 63/397,422, filed on Aug. 12, 2022.

(51) Int. Cl. G01N 15/08; G06F 30/20

(52) U.S. Cl. CPC G01N 15/08; G06F 30/20

(57) ABSTRACT

Aspects of the subject technology relate to systems, methods, and computer-readable media for identifying a relative permeability of a core sample through a computerized representation of a pore structure of the sample. Specifically, a computerized representation of a three-dimensional (3D) pore structure of a core sample can be accessed. A relative permeability of oil through the 3D pore structure can be determined in three dimensions. Further, a relative permeability of water through the 3D pore structure can be determined in the three dimensions. Average relative permeabilities of oil and water of the 3D pore structure can be identified based on the relative permeability of the oil in the three dimensions and the relative permeability of the water in the three dimensions.

### CROSS-REFERENCE TO RELATED APPLICATIONS

The present disclosure claims priority benefit of U.S. provisional patent application 63/397,422 filed on Aug. 12, 2022, and entitled “DETERMINING RELATIVE PERMEABILITY IN A ROCK SAMPLE,” the contents of which are hereby incorporated by reference.

### TECHNICAL FIELD

### Field of the Disclosure

The present technology pertains to identifying a relative permeability of a core sample through a computerized representation of a pore structure of the sample, and more particularly to determining a relative permeability of the pore structure in three dimensions from the computerized representation.

### Background

Subterranean rock formations and their associated properties are investigated for a variety of purposes including the planning and development of wellbore sites. Such evaluations may be performed when a wellbore is drilled, after a wellbore is drilled, during a production process, or during a hydraulic fracturing process. One way to evaluate subterranean formations includes extracting samples from formations of the Earth during or after the drilling of a wellbore. After samples are collected, these samples may be moved to a laboratory where an analysis is performed.

This laboratory analysis may provide information regarding how best to operate one or more wellbores such to such that production goals may be met. One limitation to this approach is that performing laboratory analysis on core samples is time consuming and expensive.

### BRIEF DESCRIPTION OF THE DRAWINGS

In order to describe the manner in which the features and advantages of this disclosure can be obtained, a more particular description is provided with reference to specific embodiments thereof which are illustrated in the appended drawings. Understanding that these drawings depict only exemplary embodiments of the disclosure and are not therefore to be considered to be limiting of its scope, the principles herein are described and explained with additional specificity and detail through the use of the accompanying drawings in which:

FIG. 1A is a schematic view of a wellbore operating environment in which a formation sample may be obtained, in accordance with various aspects of the subject technology;

FIG. 1B is a schematic view of a wellbore operating environment in which formation samples (sidewall cores) can be obtained, in accordance with various aspects of the subject technology;

FIG. 2 illustrates an example environment for performing measurement operations based on a computerized representation of pores of a core sample, in accordance with various aspects of the subject technology;

FIG. 3 illustrates a flowchart for an example method of identifying permeability of a core sample through a computer representation of a three-dimensional pore structure of the sample;

FIG. 4 illustrates actions that may be performed when core samples excavated from a wellbore are collected and evaluated;

FIG. 5 illustrates operations that may be performed when flows of fluids through subterranean formations are simulated, and

FIG. 6 illustrates an example computing device architecture which can be employed to perform various steps, methods, and techniques disclosed herein.

### DETAILED DESCRIPTION

Various embodiments of the disclosure are discussed in detail below. While specific implementations are discussed, it should be understood that this is done for illustration purposes only. A person skilled in the relevant art will recognize that other components and configurations may be used without parting from the spirit and scope of the disclosure.

Additional features and advantages of the disclosure will be set forth in the description which follows, and in part will be obvious from the description, or can be learned by practice of the principles disclosed herein. The features and advantages of the disclosure can be realized and obtained by means of the instruments and combinations particularly pointed out in the appended claims. These and other features of the disclosure will become more fully apparent from the following description and appended claims or can be learned by the practice of the principles set forth herein.

It will be appreciated that for simplicity and clarity of illustration, where appropriate, reference numerals have been repeated among the different figures to indicate corresponding or analogous elements. In addition, numerous specific details are set forth to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Described herein are systems, apparatuses, processes (also referred to as methods), and computer-readable media (collectively referred to as “systems and techniques”) for evaluating rock samples of subterranean rock formations to identify how operations of one or more wellbores may be managed efficiently and effectively. Subterranean rock formations in the Earth and their associated properties may be investigated for a variety of purposes that include yet are not limited to drilling, production management, and hydraulic fracturing. One way to evaluate subterranean formations involves extracting samples from underground formations using wellbore equipment. A first type of wellbore equipment used to extract core samples from Earth formations includes a drill bit that has a hollow space surrounded by cutting surfaces of the drill bit. As the drill bit penetrates the Earth, a cylinder of formation material is deposited in the hollow space. Such a cylindrical shaped core is commonly referred to as a “whole core.” Additionally, or alternatively, core samples may be cut from a sidewall of a wellbore. A core sample that is extracted from the sidewall of a wellbore may be referred to as a “sidewall core.” Sidewall core samples may be extracted from the wellbore after the wellbore has been drilled.

Once core samples of any sort are cut out of the Earth formation, they may be transported to the surface where these extracted core samples may be tested using various laboratory tests. Detailed analysis of such core samples may allow data about Earth formations to be identified. This data may be used to develop and train computer models such that computer models can be used identify (within threshold levels) properties of new core samples without requiring that each new core sample to be tested in a laboratory. Because of this and after a training process has been completed, laboratory analysis of new core samples may only be performed as a quality control mechanism instead of as a primary data collection methodology.

Such laboratory tests may be used to identify content of fluids included in core samples and may be used to identify properties of core samples. Sets of data collected from these tests may be used to generate maps of geological formations. Multiple core samples may be extracted throughout the length of the wellbore and samples from multiple wells may also be collected and evaluated. As such, samples from one or more wellbores may be evaluated such that structures of different subterrain formations in the Earth may be mapped in two dimensions (2D), in three dimensions (3D), or in both 2D and 3D. One limitation to relying upon laboratory testing of core samples is related to the fact that laboratory testing of core samples is a lengthy process. Other limitations relate to the high cost of performing such laboratory tests and costs associated with delaying the development of a wellbore project while waiting for lab tests to be completed. For example, it could take many months to test rock samples extracted from a field that includes numerous wellbores. Waiting for such long period of time may simply make a particular project economically impractical. While operators could simply drill without relying upon core sample analysis, doing so could lead to limiting overall production from reservoirs that exist in the Earth.

Techniques consistent with the present disclosure may use sensing apparatus of various sorts to collect data that can be used to generate images of structures contained within a core sample. The imaging of such structures may allow topologies associated with strata located in the Earth to be identified based on computer modeling techniques. This is because computer models may be used to make evaluations such that maps of Earth formations can be made more quickly and more inexpensively. This means that new forms of artificial intelligence and machine learning may help identify types of rock and properties of core samples cut out of the Earth in near-real time.

Analysis of the rock formation and of samples thereof may encompass a number of methods, including imaging and logging of properties of the samples and formations. Images of the samples may represent two dimensional (2-D) and/or three dimensional (3-D) spatial distributions of a property of particular formation samples. In certain instances, formation images may also be obtained inside wellbores. While visual or image analysis may provide information regarding the texture of a rock sample. Images of the formations and samples can be processed to identify values of additional properties or to identify surfaces separating distinct parts or components of a formation.

One such type of analysis of rock formation data may be referred to as “reservoir modeling.” Reservoir modeling can be used to predict and improve the production of hydrocarbons from a subterrain reservoir. For example, reservoir modeling may be used to identify rates at which oil should be extracted from an underground repository. In modeling such a reservoir, numerous properties of the rock formations may be identified from core samples using computerized representations of sets of respective core samples. This may include, for example, identifying porosity, absolute permeability, capillary pressure, relative permeability, and other properties of a subterranean reservoir. Such analysis may also be directed toward identifying types and quantities of fluids distributed in permeable rock. Porosity is one example of a property that affects quantities of oil, water, volatile organic compounds (e.g., forms of hydrocarbons like N-Hexane that may be present in a liquid or gaseous form), or natural gas that may be present per unit volume of rock of a subterranean geological formation. Porosity may also affect how much carbon dioxide that can be sequestered in a subterranean formation.

By identifying the size and structure of pores in rock samples, the porosity of a subterranean geological formation may be identified. Images derived from scanning core samples can be used to create a computerized representation of pores that are included in particular geological formations. In turn, relative permeability of a specific core sample can be identified based on a computerized representation of the pores included in that specific core sample. Evaluations performed by a processor executing instructions of a reservoir model may be referred to as a digital porous plate experiment. In certain instances, there may be deficiencies associated with identifying relative permeability through such a digital porous plate experiment. For example, when a simulated digital sample size is small, forecasts regarding fluid phase invasion may be more directional than actual fluid phase invasion, or forecasted flow paths that may not represent an actual flow of fluids through a subterranean reservoir.

In certain instances, the disclosed technology addresses the foregoing by generating a computerized representation of the pore structures of sets of rock samples. Once the size and structure of pores in these rock samples have been identified, volumes of oil and/or water located within an Earth formation may be identified based on calculations performed by a processor executing instructions of the computer model. Permeability of the core sample can be calculated in three dimensions and then averaged across the three dimensions to identify an overall or average permeability of specific core samples. More specifically, permeabilities of both oil and water associated with the core samples may be identified based on information associated with pores of the core sample.

A digital porous plate experiment may be performed by one or more processors that execute instructions of a computer model that simulates a real physical porous plate experiment performed in a laboratory. Additionally, calculations may be performed by one or more processors executing instructions of the computer model to identify a capillary pressure associated with the wellbore. This capillary pressure is a pressure between two immiscible fluids in pores of a core sample. The capillary pressure may result in interactions of forces between the fluids and solid walls of the pores. Capillary pressure can serve as both an opposing or driving force for fluid transport. As follows, relative permeability of the pores of the sample can be identified based on the relative permeability of the oil and the relative permeability of the water through the pores of the core sample. While fluids in a reservoir may move based on capillary action alone, fluids in a reservoir may be extracted or deposited in the reservoir by applying a pressure or suction. For example, oil may be extracted based on pump action that acts to suck oil from the reservoir.

In various instances, techniques and systems of the present disclosure may include accessing a computerized representation of a three-dimensional (3D) pore structure of a core sample. This may include determining a permeability of oil through the 3D pore structure in three dimensions and determining a permeability of water through the 3D pore structure in three dimensions. An analysis of scan data and/or image data, a permeability of the 3D pore structure can be identified in the three dimensions based on the permeability of oil in the three dimensions and the permeability of water in the three dimensions.

In various instances, a system can include one or more processors and at least one computer-readable storage medium storing instructions which, when executed by the one or more processors, cause the one or more processors to access a computerized representation of a 3D pore structure of a core sample. The instructions can also cause the one or more processors to determine a relative permeability of oil through the 3D pore structure in three dimensions. Further, the instructions can cause the one or more processors to determine a relative permeability of water through the 3D pore structure in the three dimensions. Additionally, the instructions can cause the one or more processors to identify a relative permeability of the 3D pore structure in the three dimensions based on the relative permeability of the oil in the three dimensions and the relative permeability of the water in the three dimensions.

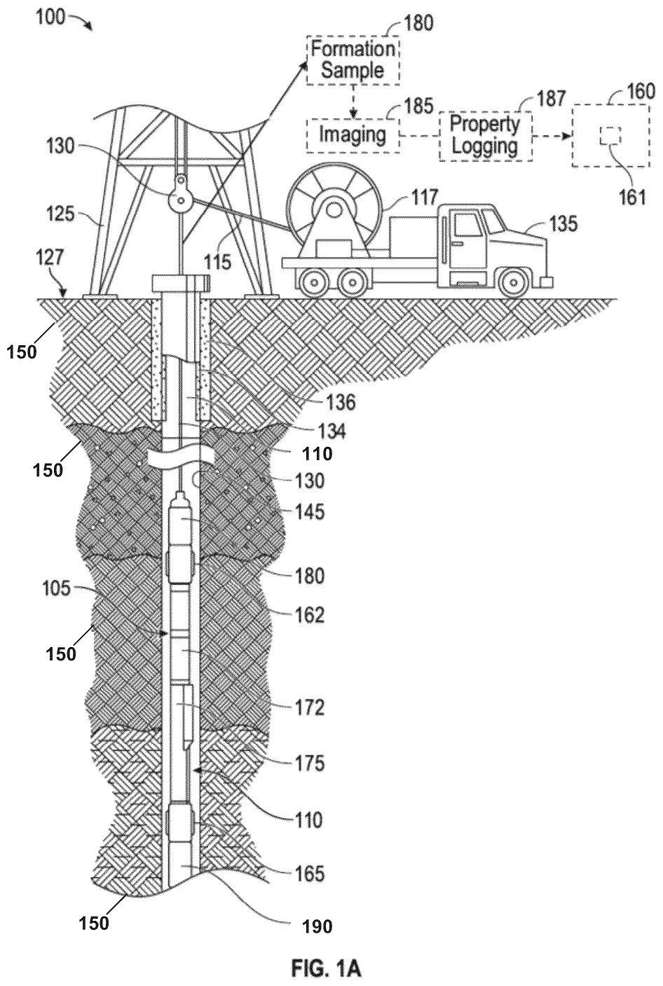

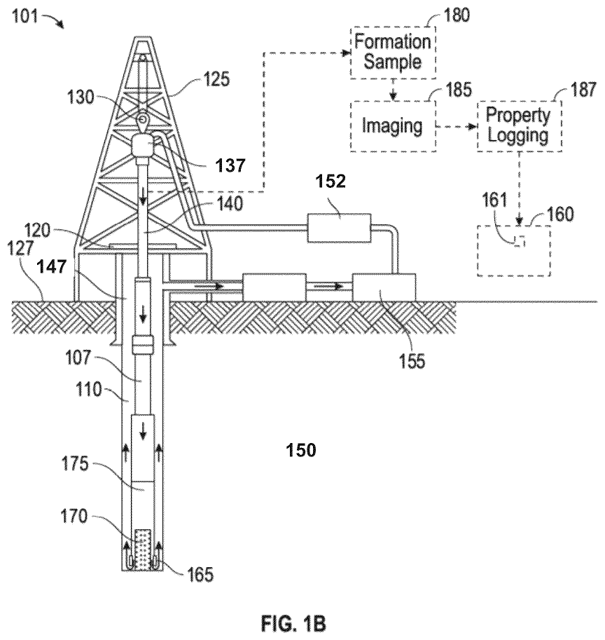

Turning now to FIG. 1A, FIG. 1A illustrates a schematic view of an embodiment of a wellbore operating environment 100 that extends through a subterranean formation from which a formation core sample may be extracted from a sidewall of the wellbore. As depicted, the operating environment 100 includes a derrick 125 that supports a hoist 130 at the surface 127 of the Earth. Here it may be assumed that a drill string has been removed from wellbore 110 to allow a downhole core sampling apparatus 105 to be lowered into wellbore 110 that has been previously drilled through one or more formations 150. As depicted, downhole core sampling apparatus 105 can be lowered into wellbore 110 by conveyance 115 coupled with hoist 130 drawn from spool 117. As shown, a casing 134 has been previously secured within the wellbore 110 by cement 136. The conveyance 115 can be anchored to derrick 125 or portable or mobile units such as truck 135. As depicted in FIG. 1A, the downhole core sampling apparatus 105 is lowered into wellbore 110 penetrating one or more formations 150 to a desired core sampling zone after which the downhole core sampling apparatus 105 may sample cores from the sidewall 145 of wellbore 110. The core sampling apparatus 105 can include an elongated housing suspended by conveyance 115 that includes an upper coupling 171, a first sealing element 162, a second sealing element 165, a sidewall coring tool 172, a core storage assembly 175, and a lower part 190 (e.g., a coupling, cap, or sensor). This core storage assembly 175 may be referred to as a core chamber used to store and move a formation core sample 180 to the surface 127.

While FIG. 1A depicts a first sealing element 162 and a second sealing element 165. A downhole core sampling apparatus 105 that includes only a single sealing element is within the spirit and scope of the present disclosure. Upon sealing engagement by first sealing element 162 and second sealing element 165, sidewall coring tool 172 may drill into or otherwise extract a formation sample from sidewall 145 of wellbore 110. The sidewall formation sample 180 may be brought to the surface 127 and subject to imaging 185, as well as formation property logging 187. The formation sample obtained may be any suitable length for testing or extraction, including about ½ inch (1.27 cm) to about 5 inches (12.7 cm), or alternatively from about 1 inch (2.54 cm) to about 4 inches (10.16 cm), or alternatively from about 1.5 inches (3.81 cm) to about 2.5 inch (6.35 cm) in length. These formation samples may be from about 1.5 to about 4 inches in diameter, or alternatively from about 2 inches to about 3 inches in diameter, or alternatively from about 2 to about 2.4 inches in diameter. The formation imaging 185 and/or property logging 187 may be carried out offsite in a laboratory. Processing center 160 may be employed for processing images, property logging and/or rendering graphics or carrying out other processing as disclosed herein and may include one or more processors 161 for such purpose. For instance, processing center 160 may be an on-site or off-site laboratory for analyzing image properties and log properties of the formation samples.

FIG. 1B illustrates an exemplary environment 101 in which a formation sample, also referred to as a core, may be extracted from a subterranean formation. The wellbore drilling environment 100 illustrates drill string 107 extending in wellbore 110 of formation 150. The drill string 107 extends from platform 120. FIG. 1B also includes platform 120 and derrick 125 that supports hoist 130. Hoist 130 may be used to raise or lower drill string 107 from the surface 127 of the Earth. Swivel 137 is provided from which an upper portion 140 of drill string 107 extends. A Kelly busing may allow drill string 107 to be rotated as it is lowered through well entrance 147. Pump 152 may be used to pump a drilling fluid in the direction shown by the arrows included in FIG. 1B. These arrows show the drilling fluid flowing down through drill string 107, then up through an annulus of wellbore 110, and horizontally to mud tank or pit 155. The processor 160 having one or more processors 161 may be provided for control of a drilling operation and/or may be used to perform analysis on acquired image data. Sample analysis may be conducted in a laboratory on site or remotely and maybe employed for processing imaging, property logging, rendering graphics, and/or for carrying out other processing as disclosed herein.

Drill string 107 may include hollowed drill bit 165. This drill bit 15 includes a hollow center or portion for receiving a formation core sample via coring tool portion 170. Drill string 107 may also include a core storage assembly 175 that receives and that retains the formation core sample from coring tool portion 170. Once the formation core sample 180 is transported to the surface images of the core sample may be acquired. Such a formation core sample 180 may be any suitable length for testing or extraction, including about ½ inch (1.27 cm) to about 5 inches (12.7 cm), or alternatively from about 1 inch (2.54 cm) to about 4 inches (10.16 cm), or alternatively from about 1.5 inches (3.81 cm) to about 2.5 inch (6.35 cm) in length. The formation samples may also be longer and may be less than 1 foot, or from 1 foot to 3 to 5 feet, or alternatively from 5 to 50 feet, or alternatively from 5 to 100 feet, or as much as 500 feet long. Longer samples may be cut into smaller samples of 1 to 4 feet for analysis. The formation sample may be extracted using coring tool portion 170 of FIG. 1B and this core sample may be in a cylindrical shape that fits within hollow drill bit 165 where it may be retained. The drill string 107 may incorporate components for logging while drilling (LWD) or measurement while drilling (MWD) which may measure various properties of the Earth formation. Data collected by LWD or MWD equipment may be communicated to the surface via one or more wires or wirelessly. Such wireless communications may be sent using an acoustic transmission or using a mud pulse telemetry signal. In this way, in addition to obtaining a formation sample during drilling, imaging and or log properties can be obtained during drilling. Alternatively, or additionally, the drill string 105 may be removed and wireline logging tools may be provided within the wellbore 110 to measure and log various properties of the formation 150, to obtain well bore images, and to extract formation samples from the walls of the well bore.

While FIGS. 1A and 1B illustrate ways of obtaining a formation sample (also referred to as cores in the field), the manner of obtaining a formation sample is not limited and may be obtained in any method. For instance, while drill bit 165 of FIG. 1B includes a hollow center, conventional drill bits may be employed, and formation cuttings and pieces of the formation obtained from conventional drilling may be used as samples.

Accordingly, formation samples may be obtained via sidewall core extraction tool 172 as shown in FIG. 1A, or via a hollow drill bit 165 as in FIG. 1B. The formation samples may be referred to as cores or core samples and may include but are not limited to whole cores (e.g., a cylindrically shaped cores), sidewall cores, slabbed cores, plugs, cuttings, formation fragments, and the like. The formation samples extracted from the wellbore or obtained in any other way can be iteratively subdivided into smaller samples (subsamples). The terms formation sample, formation core samples, or core samples encompasses the aforementioned whole cored sample, subsamples, portions of wellbore samples and fragments of samples. The term formation sample herein may also include formation components that are not extracted but which remain within the wellbore yet have been imaged or analyzed for its properties.

In order to evaluate the formation samples, imaging of the samples may be carried out. For instance, as shown in FIG. 1B, a formation sample 180, which may be the formation sample 180 or a portion thereof, may be subject to imaging 185 with an imaging device. The formation sample 180 may also be evaluated for formation properties via property logging 187 which may then be further processed in processing center 160 having one or more processors 161. As mentioned above, the imaging 185 and property logging 187 of a sample may be carried out offsite in a laboratory or elsewhere, and associated graphical rendering may be used to identify properties of an Earth formation even when laboratory analysis is not used.

Imaging performed by systems or techniques of the present disclosure may provide information regarding the physical structure, texture, and spatial distribution of properties of the formation sample or strata of the wellbore. Properties of samples taken from different locations of a wellbore may be analyzed such that images of structures of a formation may be generated and these images may identify properties of specific physical structures that are distributed throughout the formation. Data associated with such imaging may be collected using cameras or other types of sensory apparatus. While the human eye or conventional cameras cannot see through the structure of a formation sample, an imaging device may use methods which interrogate and/or detect structures throughout the interior portion of the formation sample such that images can be generated from collected data. As such, an imaging device may be employed to inspect the formation sample and obtain the desired images. Images obtained may depend on a particular property interrogated and/or detected by such sensing apparatus.

Exemplary imaging techniques include for instance, computerized tomography (CT). CT employs x-ray attenuation measurements which may involve an x-ray source that produces x-rays which may be absorbed by the formation sample, and where x-rays exiting from the formation sample are sensed by detectors. The signals produced by detectors are recorded. Signals produced at numerous angles of orientation of the core with respect to the source-detectors system are collected and processed to collectively form a 3-D image of the formation sample. The use of CT herein is only one exemplary imaging technique, as any imaging technique maybe used, including any of x-ray imaging, magnetic resonance imaging (MM), scanning electron microscopy (SEM), electrical imaging, resistivity, optical imaging, and acoustical/ultrasonic imaging. Imaging as disclosed herein may include a two-dimensional imaging (such as white-lite, UV-light, X-Ray projection, or thin section photography and the like), a three-dimensional imaging (such as a computerized tomography (CT), scanning electron microscopy (SEM)), MRI, or any other method or device suitable for evaluating 2-D or 3-D distribution of a property within the sample.

The image of a formation may represent a 2-D or 3-D distribution of a property throughout a formation. Metrics such as values of X-Ray attenuation or electrical conductivity may be identified when determining properties of the formation. Such an image may be represented in numeric form, such as an ordered collection of values of the imaged property. The image property values represent a function of two or three spatial coordinates, for example along three axes such as an X axis, a Y axis, and a Z axis. As such spatial coordinates may be associated with any spatial coordinate system and express coordinates as a function of a formation property V and a location using a linear three-dimensional (3D) coordinate system where formation property V is associated with values X1, X2, and X3—or where formation property V is associated with values of X, Y and Z.

The image properties obtained may be continuous or categorical. The continuous properties are those for which any value within certain limits defined by physical considerations is valid. For example, any value of formation density from 0 and 15 grams per cubic centimeter (g/cc) can be considered valid or within an expected range. The value of the property in this case would be continuous from 0 to 15 g/cc. Other continuous properties include resistivity, porosity, PE, etc. which may similarly be presented in a range between limits. Some properties may not have an upper or lower limit. In addition to, or alternative to continuous properties, the properties evaluated within the sample or wellbore can be categorical, or discrete, properties. Categorical properties can include, but are not limited to, facies, facies subtypes, formations, rock types, rock subtypes, petro-physical rock types, electro-facies, and clusters thereof. The types of categorical properties can be consistent throughout certain depth ranges of the earth formations, and therefore these sections can be evaluated together. The formation sample may be divided according to these categorical properties. While continuous properties are values within a range of values, categorical properties may have a singular value indicating a type or category. The singular value may be chosen from a plurality of singular values, depending on the property, each indicating a type or a category. For instance, designation of formation types can be considered as a categorical formation property, having discrete values. Each type of formation sample rock may be designated a corresponding value. Accordingly, the number of available categories corresponds to the number of formation rock types. Categorical properties can be determined at numerous depth points of interest throughout a wellbore or at different locations within the formation samples, and this determination may be based on historical knowledge of formation types or newly obtained by using or combining the geologic a priori knowledge and select measured formation properties taken both via samples in the laboratory and directly within the wellbore.

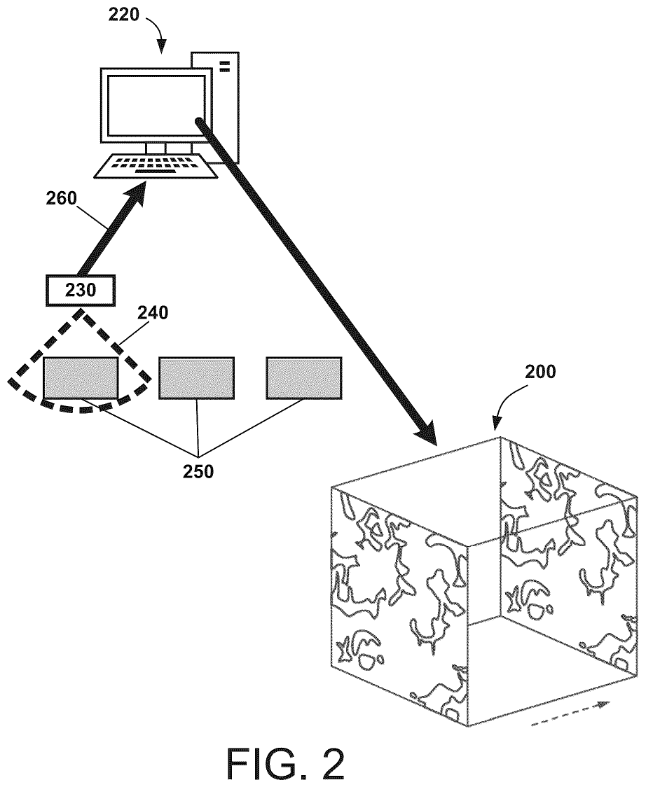

FIG. 2 illustrates an example environment for performing measurement operations based on a computerized representation of pores of a core sample. Measurement operations may include the measurement of the size and shape of pore throat cross-section using one or more digital porous plate experiments or execution sequences of a computer model. This may include identifying phase saturation in a porous sample that varies with a capillary pressure or an applied capillary pressure. Phase saturation may be defined as the fraction of pore volume occupied by a particular phase of particular substances. Phase saturation may be defined as a phase fraction in two phases distributed through pores of a sample or two phases that are distributed in a given set of pores. For example, when the pore-volume of a porous medium includes 80 percent oil and 20 percent water, the phase saturation of oil and water would be 80 percent oil and 20 percent water. In another example, when the pore-volume of a porous medium includes 70 percent oil, 20 percent gas, and 10 percent water, then the phase saturations of oil, gas, and water would be 70 percent oil, 20 percent gas, and 10 percent water.

As mentioned above, a core sample may be excavated and scanned, and data from the scan may be used to make computer-generated image 200 of the core sample. This image may have been generated at computer 220 based on data collected by scanning device 230. Scanning device 230 may be a camera or may be any type of device configured to generate data from scans 240 of core samples 250. Scanning device 230 may acquire optical data in any spectra, for example, in the visible light or infrared spectrum. Alternatively, or additionally, scanning device 230 may include an acoustic, ultrasonic, CT, MRI, SEM, or other type of scanner capable of collecting data that can be used to generate images that includes features that cannot be observed directly by a camera or the eyes of a person.

As soon as core samples 250 are removed from a wellbore they may be scanned 240 by scanner 230 and scanner 230 may provide scan data 260 to computer 220 such that one or more processors of computer 220 can execute instructions to identify properties of the core samples 250. This may result in image 200 being generated and displayed on a display of computer 220. Image data collected from a well or a plurality of wells may be used to generate maps of an entire subterranean environment.

This process may include the processor(s) of computer 220 executing instructions to identify features and properties of the scanned core samples 250. Such features may include measures of oil and/or water, oil saturation, or water saturation associated with core samples 250. Identified properties may include, pore size, permeability porosity, absolute permeability, capillary pressure, relative permeability. Each respective core sample may be associated with a depth and potentially an altitude such that locations of oil within subterranean formations may be identified. By knowing a relative altitude of the Earth's surface where one oil rig as compared to another oil rig as well as respective depths from which respective core samples were collected allows strata within the Earth to be mapped in ways that account for differences in altitude relative to a reference level (e.g., sea level). For example, a computer tomographic machine/scanner (or other type of scanner) 230 may collect data that can be evaluated to identify pore throat size and shape of pores included in core samples 250. Scanning of formation samples 250 may produce data and/or data packets 260 that may be transferable to computer 220. The data packet 260 may be uploaded to computer 220 via a communication channel, wired or wireless. In certain instances, scanner 230 may generated images that are then provided to computer 220 for further analysis and/or processing. In other instances, computer 220 may receive raw data and may generate images from that received data.

In a digital porous plate experiment, one surface of a representation of rock volume may be attached to a simulated oil reservoir through a porous plate that allows oil to pass and that blocks water. An opposite surface of the porous plate may be attached to a simulated water reservoir through a porous plate that allows water to pass and that blocks oil. By blocking the water and the oil in different surfaces, a pressure associated with the water or oil reservoirs may be maintained in the digital porous plate experiment. A pressure difference between oil and water may be considered the capillary pressure represented as Equation 1 below, where capillary pressure is represented by Pc, oil pressure is represented by Po, and water pressure is represented by Pw.

Pc=Po−Pw Equation 1

A digital experiment may start from a primary drainage state, then move to a first imbibition state, and then proceed to a second drainage state. Here again, the digital experiment may be performed by a processor executing instructions of a computer model. The movement of oil and water can be calculated using an applicable technique, such as a two-phase Lattice Boltzmann technique. These calculations may be performed to forecast the movement of oil and/or water during the first draining state, the imbibition state, and the second drainage state. The Lattice Boltzmann technique is one possible method that may be used to simulate fluid flow because it is a flexible technique that may be applied in a variety of scenarios, for example, in scenarios where complex geometries like those associated with porous media or in systems that include multiphase fluids.

In the first drainage process the capillary pressure may increase step by step. In the imbibition process the capillary pressure may decrease. The second drainage state may once again include increasing capillary pressure step by step. These simulations may be used to characterize the movement of fluids through a simulated oil reservoir and the simulation may be used to forecast a flow of oil being removed from the reservoir at a rate that maintains an oil pressure or capillary pressure when oil is extracted from the reservoir. This modeling may be used to identify any of the parameters discussed above based on data included in the mapping of a subterranean formation.

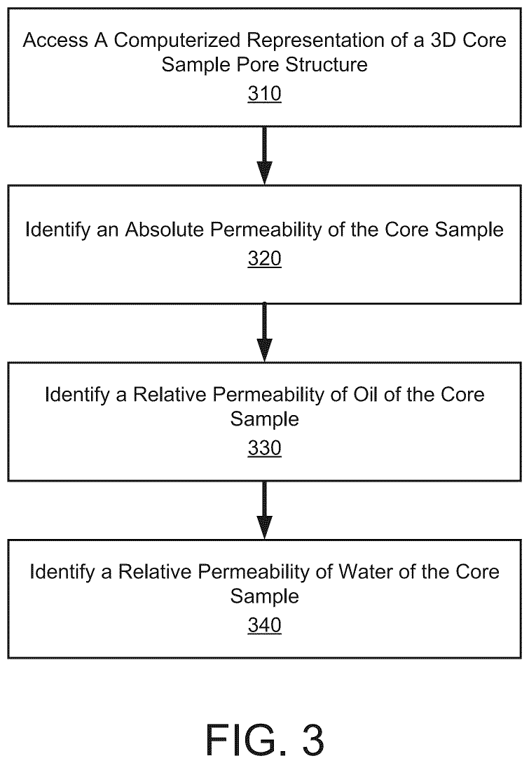

FIG. 3 illustrates a flowchart for an example method of identifying permeability of a core sample through a computer representation of a three-dimensional (3D) pore structure of a core sample. The method shown in FIG. 3 is provided by way of example, as there may be variety of ways to implement the method. At block 310, a 3D computerized representation of a pore structure of a core sample may be accessed. This representation may identify the sizes of pores of the core sample that may pass fluids, such as oil or water or a combination of both based on porosities associated with the pores of the sample. Such a sample may also include portions of rock that have different pore sizes or a cross section on the core sample may include sections that have a different porosity as compared to other sections of the core sample. Because of this, a total porosity of the core sample may be identified by averaging pore sizes over a per unit are of the sample. This average pore size and total porosity may be a function of a total volume of voids within the core sample as well as other factors.

A set of conditions may be provided to the processors as a set of input data that affect operation of the computer model. One or more processors executing instructions of the model may identify an absolute permeability of the 3D pore structure at block 320 of FIG. 3. The absolute permeability is identified using Darcy's law through a single phase flow simulation. The Darcy's law can be expressed according to Equation 2:

$$Q = \frac{Ak Δ P}{μΔ x} \qquad Equation 2$$

Here Q is the volumetric fluid flow rate through the medium, A is the area of the medium, k is the permeability of the medium, μ is the dynamic viscosity of the fluid, ΔP is the applied pressure difference, Δx is the thickness of the medium. One or more processors executing instructions of the model may identify a relative permeability of oil through the 3D pore structure as both oil and water exists in the rock sample at block 330 of FIG. 3. The one or more processors may then identify a relative permeability of water in three dimensions at block 340 based on the set of input data. This input data may identify a water pressure and an oil pressure from which a capillary pressure may be identified.

The operations discussed in respect to FIG. 3 may include accessing a computerized representation of the 3D pore structure of a core sample as discussed in respect to FIG. 2. The computerized representation can be generated through an applicable technique, such as the previously described techniques for imaging a core sample. Subsequently, computerized measurement techniques can be applied to the computerized representation.

The process of identifying the relative permeability of oil through the 3D pore structure at block 330 may include identifying three different relative permeabilities of oil corresponding to any of the three dimensions (e.g., in the X direction, Y direction, and Z direction). A relative permeability of oil at one direction is the oil permeability in the direction divided by the absolute permeability in the same direction. The relative permeability of the oil can be determined from the computerized representation of the 3D pore structure through a digital porous plate experiment. In certain instances, the relative permeability of oil can be determined using the oil distribution from the digital porous plate experiment under the assumption that an oil/water interface is fixed in the experiment.

The process of identifying the relative permeability of water through the 3D pore structure at block 320 may include identifying three different relative permeabilities of water corresponding to any of the three dimensions (e.g., in the X, Y and Z directions). Here again, the relative permeability of water can be determined from the computerized representation of the 3D pore structure through a digital porous plate experiment under the assumption that the oil/water interface is fixed in the experiment.

The relative permeabilities of water and oil can be calculated at steps 330 and 340 based on oil and water distributions in the 3D pore structure, otherwise referred to as oil and water saturation. Permeability represents the capacity for fluids to flow through a porous material. Relative permeabilities may correspond to a multi-phase flow of, for example water and oil (and possibly VOCs or natural gas) through a core sample. Specifically, a correspondence between absolute permeability ka, relative oil permeability kro, and relative water permeability ko may be expressed by Equation 3 below.

kro=ko(Sw)/ka Equation 3

The water saturation Sw is determined by counting the total water in the rock. The oil permeability kro, may be calculated using the oil occupied pores by assuming the oil water interface is fixed. The relative water permeability can be identified in the same way, e.g., based on oil distribution. Volumes of water and or oil included in a sample may have been determined based on analysis of acquired data. For example, an ultrasonic scan of a sample may be used to identify densities of materials in the sample, including materials located within the pores of the sample as well as densities of the rock. This may allow the processor(s) executing instructions of the computer model to calculate volumes of water and/or oil included in a sample.

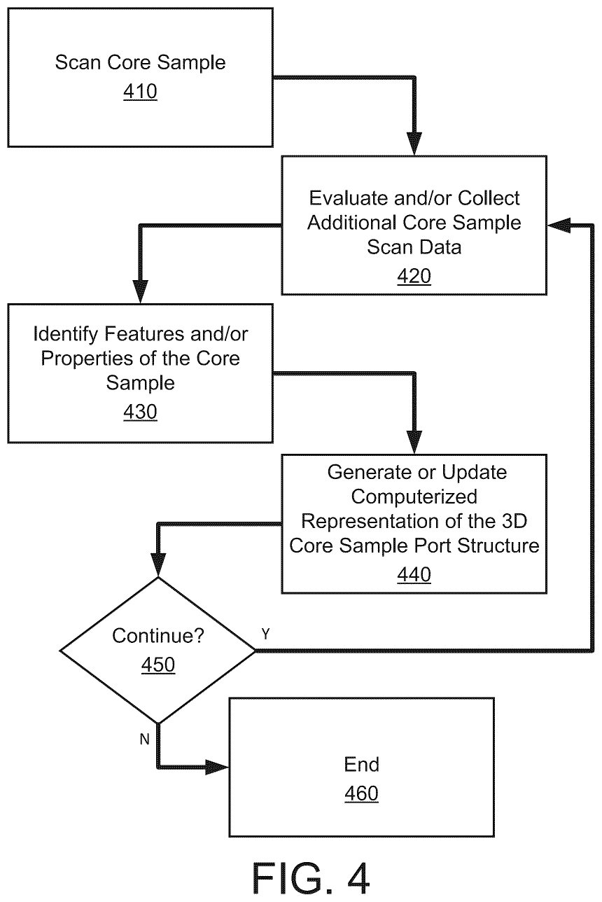

FIG. 4 illustrates actions that may be performed when core samples excavated from a wellbore are collected and evaluated. These core samples may be the whole core samples discussed in respect to FIG. 1B or the sidewall or other cores discussed in respect to FIG. 1A. Once core samples are collected, they may be scanned at by a set of cameras or other scanning equipment. As discussed in respect to FIG. 2 this may include taking pictures of the core sample and/or scanning the core sample with energy that penetrates into the structure or through the structure of the core sample. Here again such scans may collect data relating to the visible light or infrared spectra or scanning that includes one or more of acoustic scans, ultrasound scans, CT scans, MRI scans, SEM scans, or other types of scans.

Data collected from these scans may be evaluated at block 420 and this may lead to features and/or properties of the core sample(s) being identified at block 430. Properties identified at block 430 may include porosity, absolute permeability, capillary pressure, and relative permeability of a core sample. Features identified at block 430 may include a type of rock and structures within the rock. For example, such features may identify that a core sample include a mixture of sandstone and granite that affect permeability of the core sample. Such features may include structures that would resist flow of fluids in a particular direction yet include other structures that allow flow of the fluid in another direction. This means that flow of fluids through the core sample may vary across a cross-section of the core sample. A total flow of fluids through the core sample may be a summation of flows from one part of the core sample to another part of the core sample. Furthermore, an average flow of fluids through the core sample may correspond to the total flow in a particular direction divided by a cross-sectional area of the fluid flow.

Once properties and/or features of the core sample are identified at block 430, a computerized representation of the 3D core sample pore structure may be identified at block 440. This may be the same computerized representation accessed at block 310 of FIG. 3. Some properties of the core sample may be identified when a first computerized representation of the 3D core sample pore structure is generated, and this computerized representation may be updated based on additional evaluations. Determination block 450 may identify whether additional evaluations should be made on the core sample or core sample data. Each of a set of respective evaluations may be associated with a different dataset that that each in turn were collected or generated based on a different type of scan. For example, a first data set may include image data in the visual spectra, a second dataset may include image data in the infrared spectra, a third dataset may include data acquired by or generated from an acoustic or ultrasonic imaging device, and a fourth dataset may include data acquired by or generated from a CT scan. Each of the datasets may be used to generate an image (e.g., image 200 of FIG. 2) of a same core sample.

When determination block 450 identifies that additional data should be evaluated or generated, program flow may move back to block 420 where the additional core sample data are evaluated, or additional core sample data is acquired and evaluated. When determination step 450 identifies that additional evaluation should not be performed, program flow may end at block 460.

The evaluations performed at block 420 may be used to identify features of oil saturation or water saturation of a core sample. Various sets of image data may be used to identify a specific gravity of the core sample and a measure of volume of empty space that may correspond to a sum of the space between pores of the sample. Such evaluations may identify from acoustic data volumes of oil and/or water residing within a sample. Volumes of oil and or water included in a sample may be identified based on an estimated resonate frequency of a core sample. Such resonate frequencies may vary with amounts of specific fluids contained within pores of a sample. These resonate frequencies may vary in a manner similar to how a change in a volume of water in a crystal wine glass affects the resonate frequency of the crystal wine glass.

Data collected from downhole sensors may also be used to identify rock structures, pore structures and/or volumes of water or oil located within different strata of a formation. All of the information collected may be used to identify a phase saturation of oil and/or water in a sample. As mentioned above, phase saturation may be defined as the fraction of pore volume occupied by a particular phase of particular substances. For example, when the pore-volume of a porous medium includes 70 percent oil, 20 percent gas, and 10 percent water, then the phase saturations of oil, gas, and water would be 70 percent oil, 20 percent gas, and 10 percent water.

In an experiment a “drainage capillary pressure” may be identified based on a wetting phase (e.g., water) and measure the capillary pressure by increasing a saturation of the non-wetting phase (e.g., oil). This may be identical to decreasing the saturation of the wetting-phase. The process where the wetting phase saturation (e.g., water saturation) is decreased may be occur during a drainage phase—this may represent processes where the wetting phase is allowed to “drain” from the rock.

Alternatively, the core sample may be filled with the non-wetting phase (e.g., oil) and the capillary pressure identified by increasing the saturation of the wetting phase (e.g., water). This process, where the wetting phase saturation is increased, may be referred to as an imbibition phase and represents processes where the wetting phase is allowed to “imbibe” into the core. Both processes, drainage processes and imbibition processes, occur in oil and gas reservoirs.

Alternatively or additionally, simulations may be performed where a draining phase is characterized by a decrease in oil saturation and an imbibing phase is characterized by an increase in oil saturation.

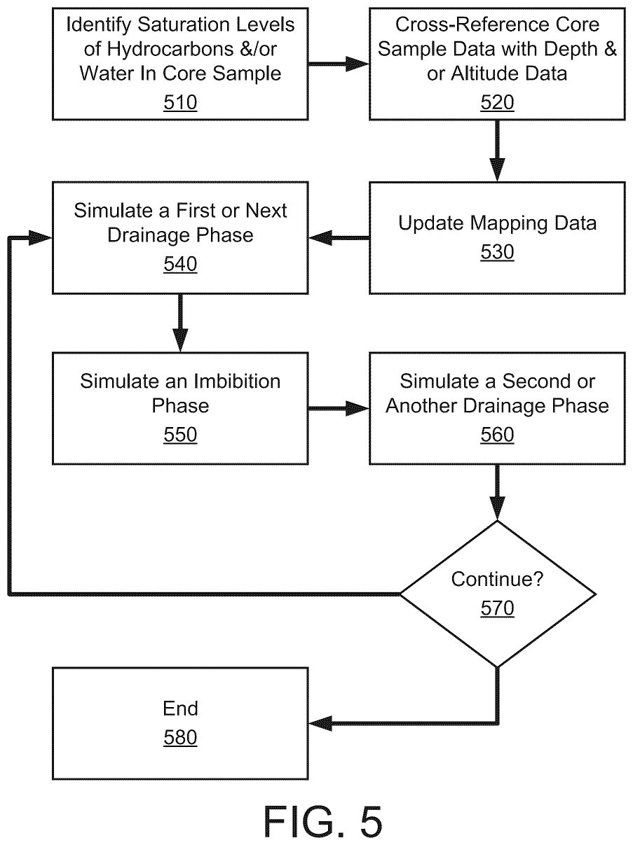

FIG. 5 illustrates operations that may be performed when flows of fluids through subterranean formations are simulated. The actions of FIG. 5 may be performed to enhance, optimize, improve, or control a production process. The steps of FIG. 5 may be performed when production of a field of wells are controlled to conform to a wellbore production plan. Data collected from core sample analysis and/or data from downhole sensors may be used to identify saturation levels of hydrocarbons and/or water that are included at specific parts of a wellbore. This may include identifying volumes of oil, gas, and/or water that are included in a core sample at block 510 of FIG. 5. The volumes of oil, gas, and/or water may be used to identify values of phase saturations to associate with the oil, the gas, and the water of the sample.

Data associated with the core sample may be cross-referenced with depth and altitude data at block 520. This may include identifying the altitude of a drilling rig relative to sea level and identifying a depth of a location where the core sample was excavated. Altitude and depth data may be used to identify a location relative to sea level where a first core sample was excavated from a first wellbore. Data from core samples excavated from one or more other wellbores may be cross-referenced with the data associated with the core sample from the first wellbore. In an instance when the first wellbore is drilled from a location that has an altitude of 100 feet above sea level and a second wellbore is drilled from a location that has an altitude of 50 feet above sea level, mappings of an oil field may be mapped considering these different altitudes. Such mappings may also identify depths at which particular strata of the Earth are located relative to sea level or another reference level. Types of rock located at different depths combined with altitude data may be used to identify whether a particular subterranean rock formation is flat or canted to some degree relative to the reference level (e.g., sea level). Such mappings may be used to identify zones within the Earth sub-strata where oil may be excavated or where carbon dioxide may be injected, for example. This data may be used to identify depths at which different wells can be operated such that a production process can be optimized, enhanced, or controlled according to a production plan.

After the core-sample data is cross-referenced with the depth and/or altitude data, a mapping of subterranean formations within the Earth may be generated or updated at block 530. Evaluations can also be performed that identify oil and/or water saturation levels associated with specific locations included in the mapping of subterranean structures. One or more processors executing instructions of a computer model may be used to simulate a first drainage stage at block 540. The simulation performed at block 540 may forecast changes in oil and/or water saturation during this first draining stage as a function of capillary pressure. As mentioned above this first saturation phase may include a step-by-step increase in capillary pressure. These increases in capillary pressure may be simulated based on pressure changes associated with the operation of pumps that suck fluids from the subterranean formation or that provide pressure to the subterranean formation.

At block 550 an imbibition phase may be simulated. This imbibition phase simulation may model a decrease in capillary pressure as a function of reduced pumping action or reduced pressure that may result an increase in saturation levels of oil and/or water. Next at block 560 a second drainage phase may be simulated. Here again this may include a step-by-step increase in capillary pressure. Determination block 560 may identify whether the simulation process should be continued, when no program flow may move to step 580 where the simulation process ends. When determination block 560 identifies that the simulation process should be continued, program flow may move back to block 540 where a next drainage phase may be simulated. As such, simulations of drainage and imbibition phases may be alternated continually until a production process is complete.

The actions performed in FIG. 5 may be performed as the production process and factors associated with the subterranean formation are monitored. A rule of a production plan may identify various factors that are defined in the production plan. For example, such rules could identify that 500 gallons of oil should be extracted per hour from an oil field based on operation of a pump that provides a level of suction. Alternatively, or additionally, gas pressures applied to other parts of the Earth formation may be identified by a rule of the production plan. A time span of a draining phase may also be identified by rules of the production plan. The production plan may also include rules regarding the imbibition phase. For example, an imbibition rule may identify that the imbibition phase should include stopping pumps that provide suction or pressure and may also identify a time that the imbibition phase should last.

Data collected from sensors that monitor a production process may be evaluated to identify whether expectations of the production process correspond to forecasts identified by the simulation. When the forecasts do not correspond to the production process expectations to a threshold degree/level, additional simulations may be performed and operations of the production process may be updated. For example, when a drainage rate is below an expected drainage rate by a threshold level, additional pump suction may be provided to the Earth formation in a simulation. In an instance when such a simulation forecasts that the production of the well should increase by an amount (e.g., by 7%) for a given increase in pump suction, the pump suction may be increased in the real physical wellbore. Additional measurements may be made to identify whether the production of the well actually increases to a level that is consistent with the expected drainage rate within the threshold level. For example, when a production plan identifies that a given well should produce 100 gallons per minute for a first pump suction level plus or minus 5% (5 GPM) and measurements indicate that only 90 gallons per minute (GPM) are being produced, a simulation may identify an increase in pump suction that should increase the production rate to be within 95 GPM to 105 GPM (i.e., 100 GPM+−5 GPM). Pump settings may be updated and actual production may be monitored again. The computer model may then be updated to account for observed differences between forecasted and measured production rates.

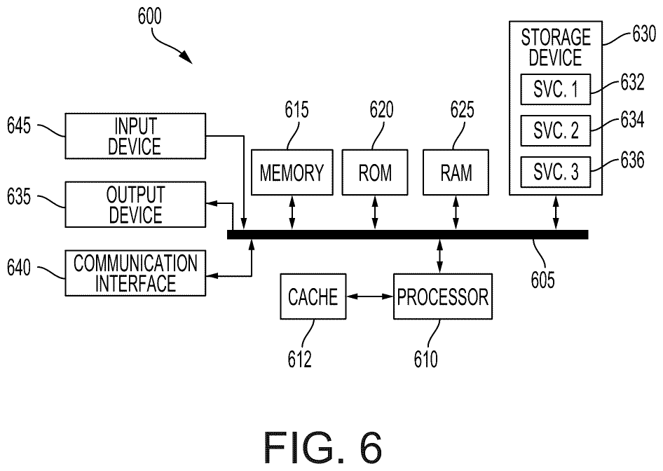

FIG. 6 illustrates an example computing device architecture 600 of a computing device which can implement the various technologies and techniques described herein. The various implementations will be apparent to those of ordinary skill in the art when practicing the present technology. Persons of ordinary skill in the art will also readily appreciate that other system implementations or examples are possible. The components of the computing device architecture 600 are shown in electrical communication with each other using a connection 605, such as a bus. The example computing device architecture 600 includes a processing unit (CPU or processor) 610 and a computing device connection 605 that couples various computing device components including the computing device memory 615, such as read only memory (ROM) 620 and random-access memory (RAM) 625, to the processor 610.

The computing device architecture 600 can include a cache of high-speed memory connected directly with, in close proximity to, or integrated as part of the processor 610. The computing device architecture 600 can copy data from the memory 615 and/or the storage device 630 to the cache 612 for quick access by the processor 610. In this way, the cache can provide a performance boost that avoids processor 610 delays while waiting for data. These and other modules can control or be configured to control the processor 610 to perform various actions. Other computing device memory 615 may be available for use as well. The memory 615 can include multiple different types of memory with different performance characteristics. The processor 610 can include any general-purpose processor/multi-processor and a hardware or software service, such as service 1 632, service 2 634, and service 3 636 stored in storage device 630, configured to control the processor 610 as well as a special-purpose processor where software instructions are incorporated into the processor design. The processor 610 may be a self-contained system, containing multiple cores or processors, a bus, memory controller, cache, etc. A multi-core processor may be symmetric or asymmetric.

To enable user interaction with the computing device architecture 600, an input device 645 can represent any number of input mechanisms, such as a microphone for speech, a touch-sensitive screen for gesture input, keyboard, mouse, motion input, speech and so forth. An output device 635 can also be one or more of a number of output mechanisms known to those of skill in the art, such as a display, projector, television, speaker device, etc. In some instances, multimodal computing devices can enable a user to provide multiple types of input to communicate with the computing device architecture 600. The communications interface 640 can generally govern and manage the user input and computing device output. There is no restriction on operating on any particular hardware arrangement and therefore the basic features here may easily be substituted for improved hardware or firmware arrangements as they are developed.

Storage device 630 is a non-volatile memory and can be a hard disk or other types of computer readable media which can store data that are accessible by a computer, such as magnetic cassettes, flash memory cards, solid state memory devices, digital versatile disks, cartridges, random access memories (RAMs) 625, read only memory (ROM) 620, and hybrids thereof. The storage device 630 can include services 632, 634, 636 for controlling the processor 610. Other hardware or software modules are contemplated. The storage device 630 can be connected to the computing device connection 605. In one aspect, a hardware module that performs a particular function can include the software component stored in a computer-readable medium in connection with the necessary hardware components, such as the processor 610, connection 605, output device 635, and so forth, to carry out the function.

For clarity of explanation, in some instances the present technology may be presented as including individual functional blocks including functional blocks comprising devices, device components, steps or routines in a method embodied in software, or combinations of hardware and software.

In some instances the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer readable media. Such instructions can include, for example, instructions and data which cause or otherwise configure a general-purpose computer, special purpose computer, or a processing device to perform a certain function or group of functions. Portions of computer resources used can be accessible over a network. The computer executable instructions may be, for example, binaries, intermediate format instructions such as assembly language, firmware, source code, etc. Examples of computer-readable media that may be used to store instructions, information used, and/or information created during methods according to described examples include magnetic or optical disks, flash memory, USB devices provided with non-volatile memory, networked storage devices, and so on.

Devices implementing methods according to these disclosures can include hardware, firmware and/or software, and can take any of a variety of form factors. Typical examples of such form factors include laptops, smart phones, small form factor personal computers, personal digital assistants, rackmount devices, standalone devices, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are example means for providing the functions described in the disclosure.

In the foregoing description, aspects of the application are described with reference to specific embodiments thereof, but those skilled in the art will recognize that the application is not limited thereto. Thus, while illustrative embodiments of the application have been described in detail herein, it is to be understood that the disclosed concepts may be otherwise variously embodied and employed, and that the appended claims are intended to be construed to include such variations, except as limited by the prior art. Various features and aspects of the above-described subject matter may be used individually or jointly. Further, embodiments can be utilized in any number of environments and applications beyond those described herein without departing from the broader spirit and scope of the specification. The specification and drawings are, accordingly, to be regarded as illustrative rather than restrictive. For the purposes of illustration, methods were described in a particular order. It should be appreciated that in alternate embodiments, the methods may be performed in a different order than that described.

Where components are described as being “configured to” perform certain operations, such configuration can be accomplished, for example, by designing electronic circuits or other hardware to perform the operation, by programming programmable electronic circuits (e.g., microprocessors, or other suitable electronic circuits) to perform the operation, or any combination thereof.

The various illustrative logical blocks, modules, circuits, and algorithm steps described in connection with the examples disclosed herein may be implemented as electronic hardware, computer software, firmware, or combinations thereof. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present application.

The techniques described herein may also be implemented in electronic hardware, computer software, firmware, or any combination thereof. Such techniques may be implemented in any of a variety of devices such as general purposes computers, wireless communication device handsets, or integrated circuit devices having multiple uses including application in wireless communication device handsets and other devices. Any features described as modules or components may be implemented together in an integrated logic device or separately as discrete but interoperable logic devices. If implemented in software, the techniques may be realized at least in part by a computer-readable data storage medium comprising program code including instructions that, when executed, performs one or more of the method, algorithms, and/or operations described above. The computer-readable data storage medium may form part of a computer program product, which may include packaging materials.

The computer-readable medium may include memory or data storage media, such as random access memory (RAM) such as synchronous dynamic random access memory (SDRAM), read-only memory (ROM), non-volatile random access memory (NVRAM), electrically erasable programmable read-only memory (EEPROM), FLASH memory, magnetic or optical data storage media, and the like. The techniques additionally, or alternatively, may be realized at least in part by a computer-readable communication medium that carries or communicates program code in the form of instructions or data structures and that can be accessed, read, and/or executed by a computer, such as propagated signals or waves.

Other embodiments of the disclosure may be practiced in network computing environments with many types of computer system configurations, including personal computers, hand-held devices, multi-processor systems, microprocessor-based or programmable consumer electronics, network PCs, minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

Various aspects of the disclosure include:
Aspect 1: A method comprising accessing a computerized representation of a three-dimensional (3D) pore structure of a core sample; determining a relative permeability of oil through the 3D pore structure in three dimensions; and determining a relative permeability of water through the 3D pore structure in the three dimensions.
Aspect 2: The method of Aspect 1, wherein the relative permeability of the oil in the three dimensions and the relative permeability of the water in the three dimensions are determined through a digital porous plate experiment.
Aspect 3: The method of any of Aspects 1 through 2, further comprising identifying a phase saturation of the at least one of the oil or the water as a function of the applied capillary pressure in the digital porous plate experiment.
Aspect 4: The method of any of Aspects 1 through 3, wherein the relative permeability of the oil in the three dimensions and the relative permeability of the water in the three dimensions are identified under the assumption that an oil water interface obtained in the digital porous plate experiment is fixed.
Aspect 5: The method of any of Aspects 1 through 4, further comprising performing a calculation to identify an average relative permeability of the oil and an average relative permeability of the water of the core sample in the three dimensions.
Aspect 6: The method of any of Aspects 1 through 5, further comprising scanning the core sample with a scanning apparatus that generates core sample scan data; and generating the computerized representation of the 3D pore structure of the core sample from the core sample scan data.
Aspect 7: The method of any of Aspects 1 through 6, further comprising identifying based on an analysis of the core sample scan data a phase saturation of at least one of the oil or the water to associate with the core sample.
Aspect 8. The method of any of Aspects 1 through 7, further comprising updating data associated with a mapping of a subterranean formation to include a measure of oil saturation associated with the core sample, wherein a production flow of the oil from the subterranean formation is adjusted based on the mapping of the subterranean formation including the measure of oil saturation associated with the core sample.
Aspect 9: A non-transitory computer-readable storage medium having embodied thereon instructions executable by one or processors to access a computerized representation of a three-dimensional (3D) pore structure of a core sample; determine a relative permeability of oil through the 3D pore structure in three dimensions; and determine a relative permeability of water through the 3D pore structure in the three dimensions.
Aspect 10: The non-transitory computer-readable storage medium of Aspect 9, wherein the relative permeability of the oil in the three dimensions and the relative permeability of the water in the three dimensions are determined through a digital porous plate experiment.
Aspect 11: The non-transitory computer-readable storage medium of any of Aspects 9 or 10, wherein the one or more processors execute the instruction to identify a phase saturation of the at least one of the oil or the water as a function of the applied capillary pressure, in the digital porous plate experiment.
Aspect 12: The non-transitory computer-readable storage medium of any of aspects 9 through 11, wherein the relative permeability of the oil in the three dimensions and the relative permeability of the water in the three dimensions are identified under based on an oil water interface obtained in the digital porous plate experiment being fixed.
Aspect 13: The non-transitory computer-readable storage medium of any of aspects 9 through 12, wherein the one or more processors execute the instructions to perform a calculation to identify an average relative permeability of the oil and an average relative permeability of the water of the core sample in the three dimensions.
Aspect 14: The non-transitory computer-readable storage medium of any of Aspects 9 through 13, wherein the one or more processors execute the instructions to initiate the scanning the core sample with a scanning apparatus that generates core sample scan data; and generate the computerized representation of the 3D pore structure of the core sample from the core sample scan data.
Aspect 15: The non-transitory computer-readable storage medium of any of Aspects 9 through 14, wherein the one or more processors execute the instructions to identify based on an analysis of the core sample scan data a phase saturation of at least one of the oil or the water to associate with the core sample.
Aspect 16. The non-transitory computer-readable storage medium of any of Aspects 9 through 15, wherein the one or more processors execute the instructions to update data associated with a mapping of a subterranean formation to include a measure of oil saturation associated with the core sample, and wherein a production flow of the oil from the subterranean formation is adjusted based on the mapping of the subterranean formation including the measure of oil saturation associated with the core sample.
Aspect 17: A system comprising: a memory; and one or more processors that execute instructions out of the computer to: access a computerized representation of a three-dimensional (3D) pore structure of a core sample, determine a permeability of oil through the 3D pore structure in three dimensions, and determine a permeability of water through the 3D pore structure in the three dimensions.
Aspect 18: The system of claim 17, wherein the relative permeability of the oil in the three dimensions and the relative permeability of the water in the three dimensions are determined through a digital porous plate experiment.
Aspect 19: The system of any of Aspects 17 or 18, wherein a phase saturation of the at least one of the oil or the water as a function of the applied capillary pressure is identified in the digital porous plate experiment.
Aspect 20: The system of any of Aspects 9 through 17, wherein a calculation to identify an average relative permeability of the oil and an average relative permeability of the water of the core sample in the three dimensions is performed.

In the above description, terms such as “upper,” “upward,” “lower,” “downward,” “above,” “below,” “downhole,” “uphole,” “longitudinal,” “lateral,” and the like, as used herein, shall mean in relation to the bottom or furthest extent of the surrounding wellbore even though the wellbore or portions of it may be deviated or horizontal. Correspondingly, the transverse, axial, lateral, longitudinal, radial, etc., orientations shall mean orientations relative to the orientation of the wellbore or tool. Additionally, the illustrate embodiments are illustrated such that the orientation is such that the right-hand side is downhole compared to the left-hand side.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or another word that substantially modifies, such that the component need not be exact. For example, substantially cylindrical means that the object resembles a cylinder, but can have one or more deviations from a true cylinder.

The term “radially” means substantially in a direction along a radius of the object, or having a directional component in a direction along a radius of the object, even if the object is not exactly circular or cylindrical. The term “axially” means substantially along a direction of the axis of the object. If not specified, the term axially is such that it refers to the longer axis of the object.

Although a variety of information was used to explain aspects within the scope of the appended claims, no limitation of the claims should be implied based on particular features or arrangements, as one of ordinary skill would be able to derive a wide variety of implementations. Further and although some subject matter may have been described in language specific to structural features and/or method steps, it is to be understood that the subject matter defined in the appended claims is not necessarily limited to these described features or acts. Such functionality can be distributed differently or performed in components other than those identified herein. The described features and steps are disclosed as possible components of systems and methods within the scope of the appended claims.

Moreover, claim language reciting “at least one of” a set indicates that one member of the set or multiple members of the set satisfy the claim. For example, claim language reciting “at least one of A and B” means A, B, or A and B.

What is claimed is:

1. A method comprising:
accessing a computerized representation of a three-dimensional (3D) pore structure of a core sample;
determining a relative permeability of oil through the 3D pore structure in three dimensions; and
determining a relative permeability of water through the 3D pore structure in the three dimensions.

2. The method of claim 1, wherein the relative permeability of the oil in the three dimensions and the relative permeability of the water in the three dimensions are determined through a digital porous plate experiment.

3. The method of claim 2, further comprising:
identifying a phase saturation of the at least one of the oil or the water as a function of the applied capillary pressure, in the digital porous plate experiment.

4. The method of claim 2, wherein the relative permeability of the oil in the three dimensions and the relative permeability of the water in the three dimensions are identified based on an oil water interface obtained in the digital porous plate experiment being fixed.

5. The method of claim 1, further comprising:
performing a calculation to identify an average relative permeability of the oil and an average relative permeability of the water of the core sample in the three dimensions

6. The method of claim 1, further comprising:
scanning the core sample with a scanning apparatus that generates core sample scan data; and
generating the computerized representation of the 3D pore structure of the core sample from the core sample scan data.

7. The method of claim 6, further comprising:
identifying based on an analysis of the core sample scan data a phase saturation of at least one of the oil or the water to associate with the core sample.

8. The method of claim 1, further comprising:
updating data associated with a mapping of a subterranean formation to include a measure of oil saturation associated with the core sample, wherein a production flow of the oil from the subterranean formation is adjusted based on the mapping of the subterranean formation including the measure of oil saturation associated with the core sample.

9. A non-transitory computer-readable storage medium having embodied thereon instructions executable by one or processors to:
access a computerized representation of a three-dimensional (3D) pore structure of a core sample;
determine a relative permeability of oil through the 3D pore structure in three dimensions; and
determine a relative permeability of water through the 3D pore structure in the three dimensions.

10. The non-transitory computer-readable storage medium of claim 9, wherein the relative permeability of the oil in the three dimensions and the relative permeability of the water in the three dimensions are determined through a digital porous plate experiment.

11. The non-transitory computer-readable storage medium of claim 10, wherein the one or more processors execute the instruction to:
identify a phase saturation of the at least one of the oil or the water as a function of the applied capillary pressure, in the digital porous plate experiment.

12. The non-transitory computer-readable storage medium of claim 11, wherein the relative permeability of the oil in the three dimensions and the relative permeability of the water in the three dimensions are identified under based on an oil water interface obtained in the digital porous plate experiment being fixed.

13. The non-transitory computer-readable storage medium of claim 9, wherein the one or more processors execute the instructions to:
perform a calculation to identify an average relative permeability of the oil and an average relative permeability of the water of the core sample in the three dimensions

14. The non-transitory computer-readable storage medium of claim 9, wherein the one or more processors execute the instructions to:
initiate the scanning the core sample with a scanning apparatus that generates core sample scan data; and
generate the computerized representation of the 3D pore structure of the core sample from the core sample scan data.

15. The non-transitory computer-readable storage medium of claim 14, wherein the one or more processors execute the instructions to:
identify based on an analysis of the core sample scan data a phase saturation of at least one of the oil or the water to associate with the core sample.

16. The non-transitory computer-readable storage medium of claim 14, wherein the one or more processors execute the instructions to:
update data associated with a mapping of a subterranean formation to include a measure of oil saturation associated with the core sample, and wherein a production flow of the oil from the subterranean formation is adjusted based on the mapping of the subterranean formation including the measure of oil saturation associated with the core sample.

17. A system comprising:
a memory; and
one or more processors that execute instructions out of the computer to:
access a computerized representation of a three-dimensional (3D) pore structure of a core sample,
determine a permeability of oil through the 3D pore structure in three dimensions, and
determine a permeability of water through the 3D pore structure in the three dimensions.

18. The system of claim 17, wherein the relative permeability of the oil in the three dimensions and the relative permeability of the water in the three dimensions are determined through a digital porous plate experiment.

19. The system of claim 18, wherein:
a phase saturation of the at least one of the oil or the water as a function of the applied capillary pressure is identified in the digital porous plate experiment.

20. The system of claim 17, wherein:
performing a calculation to identify an average relative permeability of the oil and an average relative permeability of the water of the core sample in the three dimensions is performed.
